(19) United States
(12) Patent Application Publication
(10) Pub. No.: US 2025/0012843 A1
(43) Pub. Date: Jan. 9, 2025

(54) SHORT-CIRCUIT DETECTION CIRCUIT FOR SEMICONDUCTOR SWITCH

(71) Applicant: DENSO CORPORATION, Kariya-city (JP)

(72) Inventor: Akira TOKUMASU, Kariya-city (JP)

(73) Assignee: DENSO CORPORATION, Kariya-city (JP)

(21) Appl. No.: 18/891,071

(22) Filed: Sep. 20, 2024

Related U.S. Application Data
(63) Continuation of application No. PCT/JP2023/010975, filed on Mar. 20, 2023.

(30) Foreign Application Priority Data
Mar. 24, 2022 (JP) 2022-048713

(51) Int. Cl. G01R 31/26; H03K 3/353

(52) U.S. Cl. CPC G01R 31/2601; G01R 31/2632; H03K 3/353

(57) ABSTRACT

A short-circuit detecting circuit is applied for a DESAT detecting circuit provided with a diode of which the cathode is connected to a high potential side terminal of an insulated gate type semiconductor element and a capacitor of which the first end is connected to an anode side of the diode and a second end is connected to a low potential side of the semiconductor switching element, detecting a short-circuit of the semiconductor element. The short-circuit detecting circuit includes a gate voltage terminal though which a gate voltage of the semiconductor is acquired; a DESAT voltage terminal through which a desaturation voltage corresponding to a capacitor voltage of the capacitor is acquired; and a determination circuit that detects, based on (i) the gate voltage exceeding a predetermined gate voltage threshold and (ii) the DESAT voltage exceeding a predetermined DESAT voltage threshold, a short-circuit of the semiconductor switching element.

### CROSS-REFERENCE OF RELATED APPLICATIONS

This application is the U.S. bypass application of International Application No. PCT/JP2023/010975 filed on Mar. 20, 2023, which designated the U.S. and claims priority to Japanese Patent Application No. 2022-048713 filed on Mar. 24, 2022, and the contents of both of these are incorporated herein by reference.

### BACKGROUND

### Technical Field

The present disclosure relates to a short-circuit detecting circuit that detects a short-circuit of insulated-gate type semiconductor switching elements.

### Description of the Related Art

A driving apparatus of a semiconductor switching element connected to a desaturation (DESAT) detecting circuit for detecting a short circuit of semiconductor switching elements is known. This driving apparatus has a protection function that detects a short-circuit between semiconductor switching elements, thereby preventing semiconductor switching elements from being damaged due to an overcurrent.

### SUMMARY

The present disclosure provides first and second short-circuit detecting circuits applied for a DESAT detecting circuit provided with a diode of which the cathode is connected to a high potential side terminal of an insulated gate type semiconductor element and a capacitor of which the first end is connected to an anode side of the diode and a second end is connected to a low potential side of the semiconductor switching element, detecting a short-circuit of the semiconductor element. The first short-circuit detecting circuit includes: a gate voltage terminal though which a gate voltage of the semiconductor is acquired; a DESAT voltage terminal through which a desaturation voltage corresponding to a capacitor voltage of the capacitor is acquired; and a determination circuit that detects, based on (i) the gate voltage exceeding a predetermined gate voltage threshold and (ii) the DESAT voltage exceeding a predetermined DESAT voltage threshold, a short-circuit of the semiconductor switching element. The second short-circuit detecting circuit according to the present disclosure is provided with a DESAT voltage terminal through which a desaturation voltage corresponding to a capacitor voltage of the capacitor is acquired, a timer that measures an elapsed time from a predetermined timing, and a determination circuit that detects a short-circuit on the semiconductor switching element when the elapsed time measured by the timer exceeds a predetermined time and the DESAT voltage exceeds a predetermined DESAT voltage threshold.

### BRIEF DESCRIPTION OF THE DRAWINGS

The above-described objects and other objects, features and advantages of the present disclosure will be clarified further by the following detailed description with reference to the accompanying drawings.

The drawings are:

FIG. 1 is a circuit diagram including a short-circuit detecting circuit of a semiconductor switching element according to a first embodiment;

FIG. 2 is a diagram showing short-circuit detection for the semiconductor switching element according to the first embodiment;

FIG. 3 is a circuit diagram including a short-circuit detecting circuit of a semiconductor switching element according to a second embodiment;

FIG. 4 is a diagram showing short-circuit detection for the semiconductor switching element according to the second embodiment;

FIG. 5 is a circuit diagram including a short-circuit detecting circuit of a semiconductor switching element according to a third embodiment;

FIG. 6 is a diagram showing short-circuit detection for the semiconductor switching element according to the third embodiment;

FIG. 7 is a circuit diagram including a short-circuit detecting circuit of a semiconductor switching element according to a fourth embodiment;

FIG. 8 is a diagram showing short-circuit detection for the semiconductor switching element according to the fourth embodiment;

FIG. 9 is a diagram showing short-circuit detection for a semiconductor switching element according to a modification example; and

FIG. 10 is a diagram showing short-circuit detection for a semiconductor switching element according to a modification example.

### DETAILED DESCRIPTION OF THE PREFERRED EMBODIMENTS

A driving apparatus of a semiconductor switching element connected to a desaturation (DESAT) detecting circuit for detecting a short circuit of semiconductor switching elements is known. This driving apparatus has a protection function that detects a short-circuit between semiconductor switching elements, thereby preventing semiconductor switching elements from being damaged due to an overcurrent.

According to a patent literature, Japanese Patent Number 5861787, an IGBT driving apparatus is connected to a desaturation detecting circuit including a diode and a capacitor and provided with a constant current source for charging the capacitor. Specifically, in order to protect the IGBT devices when a short-circuit occurs during an ON period of the IGBT device, the IGBT driving apparatus charges, when the driving signal is ON, the capacitor using the constant current source and charges the capacitor using a larger constant current source after reaching the saturation voltage.

According to the above-described patent literature, it is difficult to shorten the charging period of the capacitor to adjust a masking time of a short-circuit detection using a delay time of the capacitor charging. Hence, it is difficult to shorten a period for detecting a short-circuit of the IGBT device.

### First Embodiment

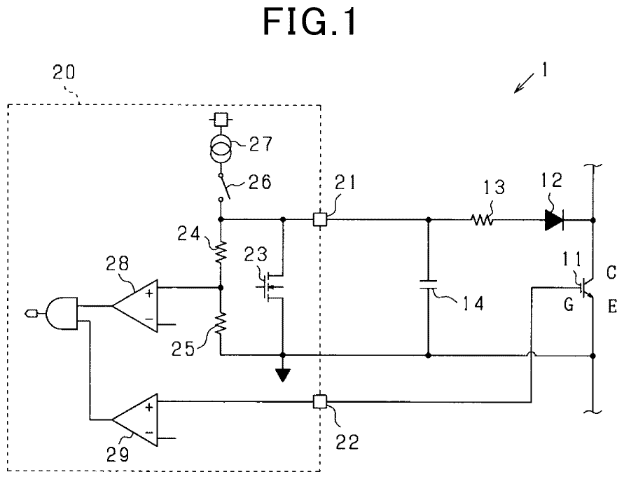

FIG. 1 shows a circuit diagram including a desaturation (DESAT) detecting circuit 1 connected to an IGBT 11 as an example of a semiconductor switching element in an insulation gate side and a short-circuit detecting circuit 20. The IGBT 11 is used as a switching element that constitutes an inverter circuit, for example. The IGBT 11 may be parallelly connected to a reflux diode. The short-circuit detecting circuit 20 may be included in a driving IC that drives the IGBT 11, for example.

The DESAT detecting circuit 1 is provided with a diode 12, a DESAT resistor 13 and a capacitor 14. The short-circuit detecting circuit 20 includes a DESAT voltage terminal 21, a gate voltage terminal 22, a MOFET 23, a first resistor 24 and a second resistor 25, a switch 26, a constant current source 27 and comparators 28 and 29. The short-circuit detecting circuit 20 is connected to the DESAT detecting circuit 1 via the DESAT voltage terminal 21, and is connected to the gate of the IGBT 11 via the gate voltage terminal 22.

The collector of the IGBT 11 is connected to the diode 12 and the emitter of the IGBT 11 is connected to the MOSFET 23 and the second resistor 25. The diode 12 connects between the DESAT voltage terminal 21 and the collector of the IGBT 11 via the DESAT resistor 13. The diode 12 serves as a diode of which the forward direction is a direction towards the IGBT 11 from the DESAT voltage terminal 21. A first end of the capacitor 14 is connected to a connection wiring that connects between the DESAT resistor 13 and the DESAT voltage terminal 21 and is connected to an anode side of the diode 12 via the DESAT resistor 13. A second end of the capacitor 14 is connected to the emitter of the IGBT 11.

The short-circuit detecting circuit 20 is connected to the DESAT detecting circuit 1 via the DESAT voltage terminal 21, whereby a DESAT voltage corresponding to the capacitor 14 is detected. The DESAT voltage is monitored, whereby a charge voltage of the capacitor 14 is monitored. The short-circuit detecting circuit 20 is connected to the gate of the IGBT 11 via the gate voltage terminal 22, whereby the gate voltage of the IGBT 11 is detected.

The first resistor 24 and the second resistor 25 are connected in series. A first end of the first resistor 24 is connected to the DESAT voltage terminal 21 and connected to a constant current source 27 via a switch 26, and a second end of the first resistor 24 is connected to the second resistor 25. A first end of the second resistor 25 is connected to the first resistor 24 and a second end thereof is connected to the emitter of the IGBT 11. For the MOSFET 23, the drain is connected to a connection wiring that connects between the first resistor 24 and the DESAT voltage terminal 21, and the source is connected to the emitter of the IGBT 11. The capacitor 14 is charged when the switch 26 is ON and the MOSFET 23 is OFF. The capacitor 14 is discharged in response to turn-ON of the MOSFET 23 when the capacitor 14 is being charged.

The positive terminal of the comparator 28 is connected to a portion between the first resistor 24 and the second resistor 25. The negative terminal of the comparator 28 is connected to a capacitor threshold voltage source (not shown) which outputs a DESAT voltage threshold. The negative terminal of the comparator 29 is connected to the gate threshold voltage source (not shown) which outputs a gate voltage threshold. The output terminals of the comparators 28 and 29 are connected to an AND circuit.

The DESAT detecting circuit 1 is provided with a diode 12 of which the cathode is connected to the collector of the IGBT 11 as a high potential side terminal, and the capacitor 14 of which the first end is connected to the anode side of the diode 12 and a second end is connected to the emitter of the IGBT as a low potential side terminal. The short-circuit detecting circuit 20 is applied to the DESAT detecting circuit 1 and has a function of detecting a short-circuit of the IGBT 11. According to the short-circuit detecting circuit 20, with the DESAT voltage terminal 21, the gate voltage terminal 22 and the comparators 28 and 29 connected to the AND circuit, occurrence of a short-circuit is detected. Specifically, when the gate voltage inputted to the positive terminal of the comparator 29 exceeds the gate voltage threshold inputted to the negative terminal thereof and the DESAT voltage inputted to the positive terminal of the comparator 28 exceeds the DESAT voltage threshold, the output of the AND circuit turns to be active. Hence, occurrence of a short-circuit of the IGBT 11 can be detected. The AND circuit and the comparators 28 and 29 serve as a determination circuit that detects occurrence of a short-circuit of the IGBT 11. In the short-circuit detecting circuit 20, a masking time is secured by detecting the gate voltage exceeding a predetermined gate voltage.

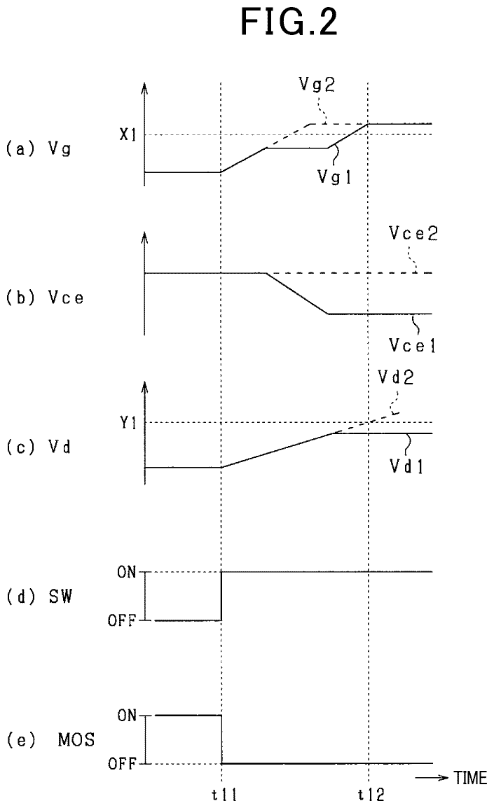

FIG. 2 illustrates a timing diagram in the case where the IGBT 11 turns ON. The vertical axis of FIG. 2 indicates, from the above to the bottom in the timing diagram, (a) gate voltage Vg of IGBT 11, (b) voltage Vce between the collector and emitter of the IGBT 11, (c) DESAT voltage Vd, (d) ON-OFF state of switch 26 and (e) ON-OFF state of the MOSFET 23. The horizontal axis of FIG. 2 indicates time.

As shown in FIG. 2, when the IGBT 11 turns ON, the gate voltage Vg starts to increase. At time t11, when the MOSFET 23 changes its state from ON to OFF and the switch 26 changes its state from OFF to ON, the current is supplied to the capacitor 14 from the constant current source 27. Thus, the DESAT voltage Vd starts to increase.

In a normal state where no short-circuit failure occurs on the IGBT 11, the voltage Vce between the collector and the emitter of the IGBT 11 decreases to a saturation voltage. Then, the charge voltage of the capacitor 14 connected in parallel between the collector and the emitter of the IGBT 11 is clamped at a voltage that is the same as the saturation voltage of the IGBT 11. At this moment, the constant current flowing from the constant current source 27 flows to the IGBT 11 via the diode 12. Hence, in the normal state, as shown in FIG. 2 (timings (a) to (c)) indicating by the solid lines Vg1, Vce1 and Vd1, the collector-emitter voltage Vce1 decreases to the saturation voltage, whereby an increase in the DESAT voltage Vd1 is stopped and the DESAT voltage Vd1 becomes substantially constant value which is lower than the DESAT voltage threshold Y1. Further, an increase in the gate voltage Vg1 is stopped and the gate voltage Vg1 becomes substantially constant value which is lower than the gate voltage threshold X1. Thereafter, an increase in the gate voltage Vg1 is resumed and the gate voltage Vg1 becomes substantially constant value higher than the gate voltage threshold X1. At this moment, the DESAT voltage Vd1 is a substantially constant voltage lower than the DESAT voltage threshold Y1. In the normal state, since it does not satisfy a condition of Vd1>Y1 and Vg1>X1, the AND circuit included in the short-circuit detecting circuit 20 does not output a signal indicating a short-circuit of the IGBT 11. Note that a period where the gate voltage detected after turning ON of the IGBT 11 is maintained at a constant voltage is referred to as a mirror period, and the gate voltage in the mirror period is referred to as a mirror voltage. The gate voltage threshold X1 is set to be higher than the mirror voltage of the IGBT 11.

In contrast, when a short-circuit failure has occurred on the IGBT 11, the collector-emitter voltage Vce after the turning ON of the IGBT 11 becomes unsaturated and the charge voltage of the capacitor 14 cannot be clamped at the saturation voltage. That is, when the collector-emitter voltage Vce is unsaturated, the voltage at the cathode side of the diode 12 increases and the constant current flows to the capacitor 14 side from the constant current source 27. When the constant current is supplied, the capacitor 14 is further charged. Hence, when a shot-circuit occurs, as shown in FIG. 2 indicating timings (a) to (c) with the dotted lines, the collector-emitter voltage Vce2 does not decrease, causing an unsaturated state. Hence, the gate voltage Vg2 and the DESAT voltage Vd2 continue to increase. As a result, the gate voltage Vg2 exceeds the gate voltage threshold X1 and the DESAT voltage Vd2 exceeds the DESAT voltage threshold Y1. At time t12, when the condition satisfies Vg2>X1 and Vd2>Y1, an occurrence of a short-circuit on the IGBT 11 can be detected using the output of the AND circuit included in the short-circuit detecting circuit 20.

According to the first embodiment, detecting that the gate voltage exceeds a predetermined gate voltage threshold, a masking time can be secured. Since the masking time for detecting a short-circuit detection is not necessarily adjusted with a design of the capacitor 14, the current supplied to the capacitor 14 from the constant current source 27 is set to be increased, whereby the charging time of the capacitor 14 can be designed to be shorter. As a result, a short-circuit of the IGBT 11 can be promptly detected.

### Second Embodiment

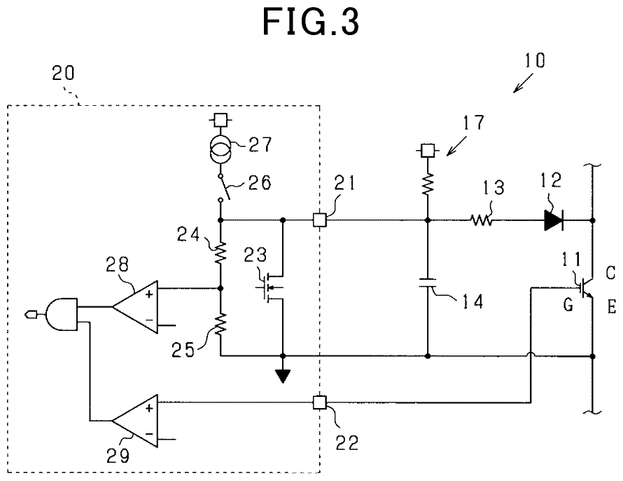

FIG. 3 shows a circuit diagram including a DESAT detecting circuit 10 and a short-circuit detecting circuit 20 according to a second embodiment. The DESAT detecting circuit 10 differs from the DESAT detecting circuit 1 shown in FIG. 1 in that the DESAT detecting circuit includes a charge resistor 17. The charge resistor 17 is connected to the capacitor 14 at a connection wiring that connects between the DESAT resistor 13 and the DESAT voltage terminal 21. As a resistor connected to the capacitor 14, the charge resistor 17 is provided, whereby a rate of change of the voltage at the capacitor 14 can be higher when switching the IGBT 11.

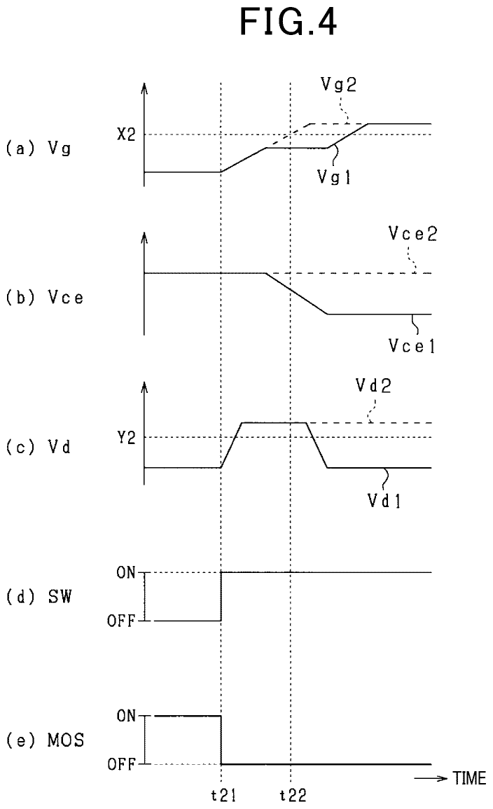

FIG. 4 shows a timing diagram of the IGBT 11 when switching. The vertical axis of FIG. 4 indicates, from the above to the bottom in the timing diagram, (a) gate voltage Vg of the IGBT 11, (b) collector-emitter voltage Vce of the IGBT 11, (c) DESAT voltage Vd, (d) ON-OFF state of the switch 26 and (e) ON-OFF state of the MOSFET 23. The horizontal axis of FIG. 4 indicates time.

As shown in FIG. 4, when the IGBT 11 turns ON, the gate voltage Vg starts to increase. At time t21, in the case where the MOSFET 23 turns to the OFF state from the ON state, and the switch 26 turns to the ON state from the OFF state, current is supplied to the capacitor 14 from the constant current source 27. Thus, the DESAT voltage Vd starts to increase. Since the charge resistor 17 is provided, in the case shown in timing (c) of FIG. 4, a rate of change of the DESAT voltage Vd is higher than the case shown in timing (c) of FIG. 2. In the case where the charge resistor 17 is provided, since the capacitor 14 can be promptly charged without supplying current from the constant current source 27 to the capacitor 14, the constant current source may not be provided.

In a normal state where no short-circuit failure occurs on the IGBT 11, as shown in FIG. 4 (timings (a) to (c)) indicating by the solid lines Vg1, Vce1 and Vd1, the collector-emitter voltage Vce1 decreases to the saturation voltage, whereby an increase in the gate voltage Vg1 is stopped and becomes substantially constant value which is lower than the gate voltage threshold X2. On the other hand, since a rate of change of the DESAT voltage Vd1 is higher than that of the first embodiment, the DESAT voltage Vd1 temporarily exceeds the DESAT voltage threshold Y2, and the collector-emitter voltage Vce1 is lowered, then the DESAT voltage Vd1 becomes substantially constant value lower than the DESAT voltage threshold Y2. Although the condition of Vd1>Y2 is satisfied, a condition of Vg1>X2 is not satisfied. Hence, the AND circuit included in the short-circuit detecting circuit 20 does not output a signal indicating a short-circuit of the IGBT 11. Then, after the gate voltage Vg1 restarts to increase, and becomes substantially constant value higher than the gate voltage threshold value X1. At this moment, the DESAT voltage Vd1 is substantially constant value lower than the DESAT voltage threshold Y1. In the normal state, since conditions Vd1>Y1 and Vg1>X1 are not satisfied, the AND circuit included in the short-circuit detecting circuit 20 does not output a signal indicating a short-circuit of the IGBT 11.

In contrast, when a short-circuit failure has occurred on the IGBT 11, as shown in FIG. 4 (timings (a) to (c)) indicating by the dotted lines Vg2, Vce2 and Vd2, the collector-emitter voltage Vce2 does not decrease, causing an unsaturated state, whereby an increase in the gate voltage Vg2 and the DESAT voltage Vd2 is not stopped. As a result, the gate voltage Vg2 exceeds the gate voltage threshold X2 and the DESAT voltage Vd exceeds the DESAT voltage threshold Y2. At time t22, when conditions show Vg2>X2 and Vd2>Y2, a short-circuit of the IGBT 11 can be detected using the output of the AND circuit included in the short-circuit detecting circuit 20.

According to the second embodiment, when detecting that the gate voltage exceeds a predetermined gate voltage threshold, the masking time can be secured. Hence, the charge resistor 17 is provided to shorten the charging time of the capacitor 14. As a result, in the normal state of the IGBT 11, even when the DESAT voltage Vd temporarily exceeds the DESAT voltage threshold Y2, a short-circuit of the IGBT 11 can be prevented from being erroneously detected. Therefore, a circuit design for promptly detecting a short circuit of the IGBT 11 can be accomplished by applying faster charging time of the capacitor 14 and the like.

### Third Embodiment

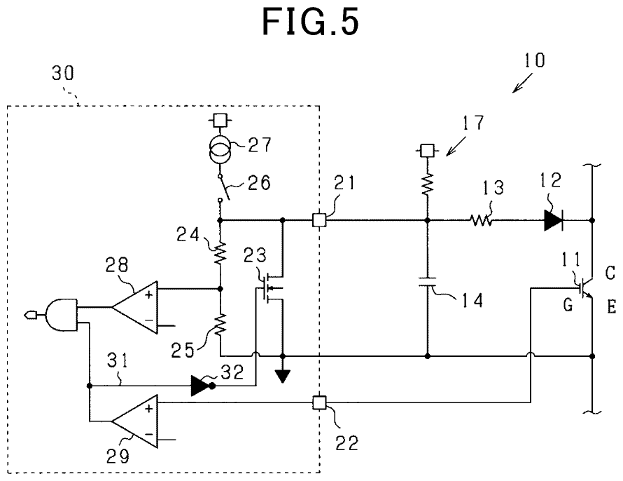

FIG. 5 shows a circuit diagram including a DESAT detecting circuit 10 and a short-circuit detecting circuit 30 according to a third embodiment. The short-circuit detecting circuit 30 differs from the short-circuit detecting circuit 20 in that a wiring 31 is provided including a gate of the MOSFET 23 and an inverting (NOT) circuit 32 that inverts the output of the comparator 29. According to the wiring 31, the MOSFET 23 can be turned OFF at a time when the output of the comparator 29 is active. That is, the wiring 31 functions as a charge timing control circuit that controls a start timing of the charging of the capacitor 14 to be a time when the gate voltage transmitted via the gate voltage terminal 22 exceeds the gate voltage threshold. Note that at least one of the charge resistor 17 and the constant current source 28 may be provided.

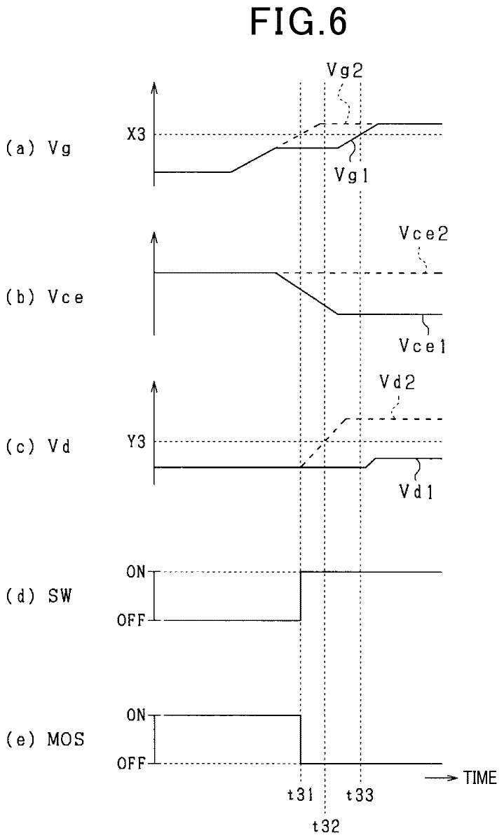

FIG. 6 shows a timing diagram the IGBT 11 when switching. The vertical axis of FIG. 6 indicates, from the above to the bottom in the timing diagram, (a) gate voltage Vg of the IGBT 11, (b) collector-emitter voltage Vce of the IGBT 11, (c) DESAT voltage Vd, (d) ON-OFF state of the switch 26 and (e) ON-OFF state of the MOSFET 23. The horizontal axis of FIG. 6 indicates time.

As shown in FIG. 6, when the IGBT 11 turns ON, the gate voltage Vg starts to increase. In a normal state where no short-circuit failure occurs on the IGBT 11, as shown in FIG. 6 (timings (a) to (c)) indicating by the solid lines Vg1, Vce1 and Vd1, when the gate voltage Vg1 exceeds the gate voltage threshold X3, the collector-emitter voltage Vce1 is saturated and lowered. Hence, the DESAT voltage Vd1 barely increases and becomes substantially constant value lower than the DESAT voltage threshold Y3. Even when a condition Vg1>X3 is satisfied at time t33, a condition Vd1>Y3 is not satisfied. Accordingly, the AND circuit included in the short-circuit detecting circuit 30 does not output a signal indicating a short-circuit of the IGBT 11.

When a short-circuit failure has occurred on the IGBT 11, as shown in FIG. 6 (timings (a) to (c)) indicating by the dotted lines Vg2, Vce2 and Vd2, at time t31, the gate voltage Vg exceeds the gate voltage threshold X3. Hence, at time t31, the MOSFET 23 changes the state from ON state to OFF state, the switch 26 changes the state from the OFF state to the ON state, and the current is supplied to the capacitor 14 from the constant current source 27. Accordingly, the DESAT voltage Vd starts to increase. At time t32, when the conditions of Vg2>X3 and Vd2>Y3 are satisfied, an occurrence of a short-circuit on the IGBT 11 can be detected using the output of the AND circuit included in the short-circuit detecting circuit 30.

According to the third embodiment, charging of the capacitor 14 is started at a timing where the gate voltage exceeds a predetermined gate voltage threshold. Hence, in the normal state of the IGBT 11, the DESAT voltage Vd starts to increase in a state where the collector-emitter voltage is lowered, but the DESAT voltage Vd barely increase and is maintained at substantially constant, thus preventing the DESAT voltage from exceeding the DESAT voltage threshold Y3. As a result, a short-circuit of the IGBT 11 can be prevented from being erroneously detected. Therefore, a circuit design for promptly detecting a short circuit of the IGBT 11 can be accomplished by applying faster charging time of the capacitor 14 and the like.

### Fourth Embodiment

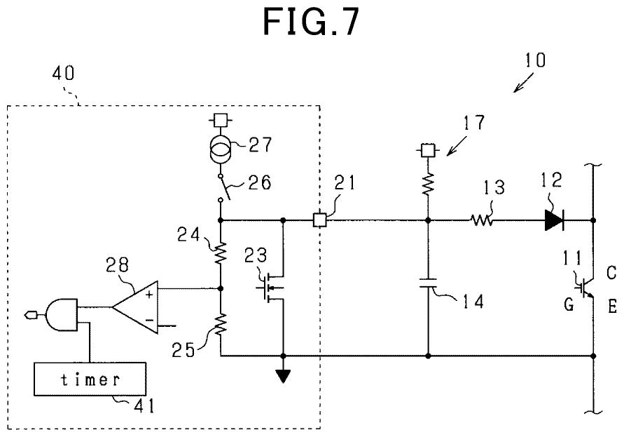

FIG. 7 shows a circuit diagram including a DESAT detecting circuit 10 and a short-circuit detecting circuit 40 according to a fourth embodiment. The short-circuit detecting circuit 40 differs from the short-circuit detecting circuit 20 in that the gate voltage terminal 22 is not provided and a timer 41 is provided instead of the comparator 29. The timer 41 measure an elapsed time from a predetermined timing and outputs a signal indicating that the elapsed time measured by the timer 41 exceeds a predetermined period. The AND circuit, the comparator 28 and the timer 41 functions as a determination circuit that detects a short-circuit of the IGBT 11. The determination circuit detects that a short-circuit occurs on the IGBT 11 when the elapsed time measured by the timer 41 exceeds a predetermined period and the DESAT voltage exceeds the DESAT voltage threshold.

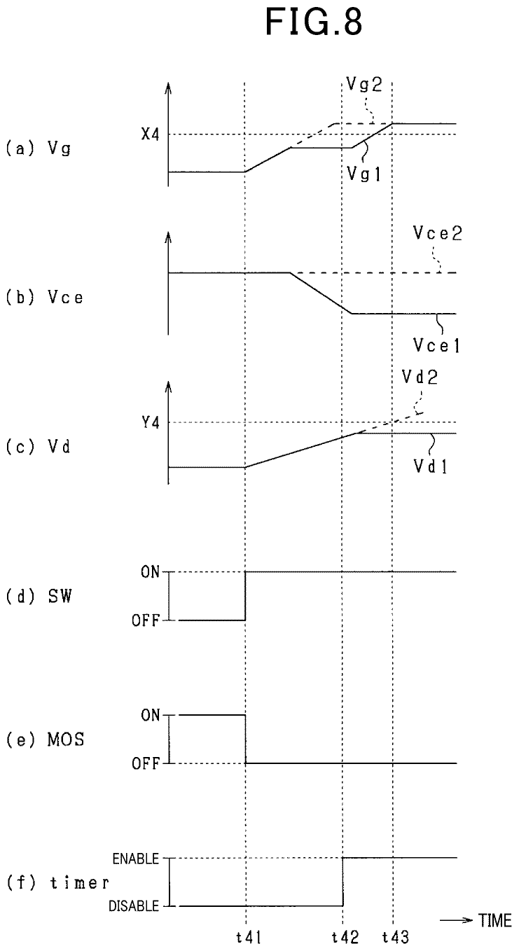

FIG. 8 shows a timing diagram of the IGBT 11 when switching. The vertical axis of FIG. 8 indicates, from the top to the bottom in the timing diagram, (a) gate voltage Vg of IGBT 11, (b) voltage Vce between the collector and emitter of the IGBT 11, (c) DESAT voltage Vd, (d) ON-OFF state of switch 26, (e) ON-OFF state of the MOSFET 23 and (f) enable-disable state of the timer. The horizontal axis of FIG. 2 indicates time. Note that the gate voltage Vg is shown as a reference and the gate voltage Vg is not acquired by the short-circuit detecting circuit 40.

As shown in FIG. 8, when the IGBT 11 turns ON, the gate voltage Vg starts to increase. At time t41, when the MOSFET 23 is changed from ON state to OFF state, and the switch 26 changes the state from OFF to ON, current is supplied to the capacitor 14 from the constant current source 27. Thus, the DESAT voltage Vd starts to increase. The timer 41 sets time t41 to be a predetermined timing and measures a time elapsed from time t41.

In a normal state where no short-circuit failure occurs on the IGBT 11, as shown in FIG. 8 (timings (b) and (c)) indicating by the solid lines Vce1 and Vd1, the collector-emitter voltage Vce1 decreases to the saturation voltage, whereby an increase in the DESAT voltage Vd1 is stopped and the DESAT voltage Vd1 becomes substantially constant value which is lower than the DESAT voltage threshold Y4.

In contrast, in a short-circuit failure state where a short-circuit failure occurs on the IGBT 11, as shown in FIG. 8 (timings (b) and (c)) indicating by the dotted lines Vg2, Vce2 and Vd2, the collector-emitter voltage Vce2 does not decrease, causing an unsaturated state. Hence, the gate voltage Vg2 and the DESAT voltage Vd2 continue to increase. As a result, the DESAT voltage Vd exceeds the DESAT voltage threshold Y4. The time t42 refers to a time when a predetermined time elapses from time t41. In the case where the state of the timer 41 switches from the disabled state to the enabled state at time t42, and then a condition Yd2>Y4 is satisfied at time t43, a short-circuit of the IGBT 11 can be detected with the AND circuit included in the short-circuit detecting circuit 40

According to the fourth embodiment, the masking time can be secured by the timer 41. Since the masking time for detecting a short-circuit is not necessarily adjusted with a design of the capacitor 14, the current supplied to the capacitor 14 from the constant current source 27 is set to be increased, whereby the charging time of the capacitor 14 can be designed to be shorter. As a result, a short-circuit of the IGBT 11 can be promptly detected.

### MODIFICATION EXAMPLE

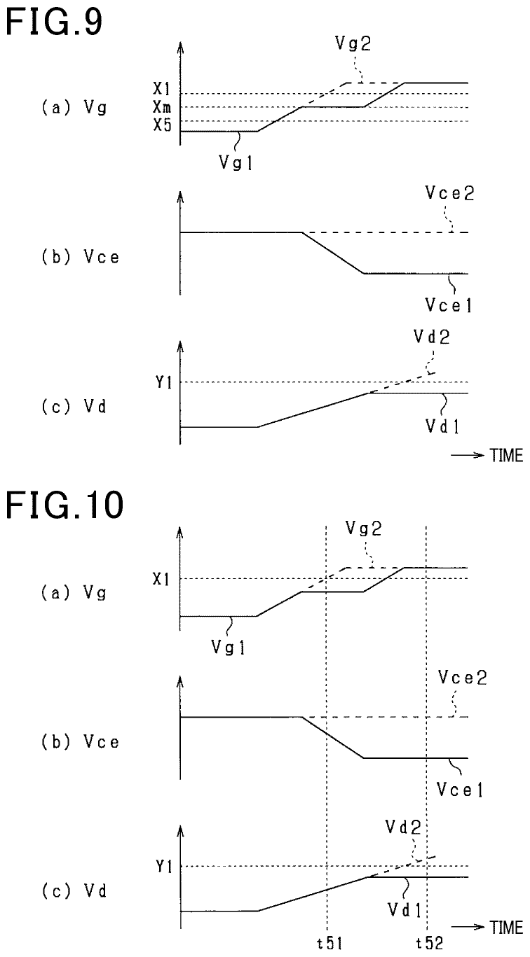

According to the above-described embodiments, it is exemplified that the gate voltage threshold is set to be higher than a mirror voltage Xm. However, it is not limited thereto. Similar to the gate voltage threshold X5 shown in FIG. 9, the gate voltage threshold may be set to be lower than or equal to the mirror voltage Xm of the IGBT 11.

According to the above-described embodiments, in the case where a short-circuit failure is detected when the gate voltage Vg exceeds the gate voltage threshold and the DESAT voltage exceeds the DESAT voltage threshold, a short-circuit failure is detected any time when the DESAT voltage exceeds the DESAT voltage threshold while the gate voltage Vg exceeds the gate voltage threshold. However, it is not limited thereto. As shown in FIG. 10, a short-circuit failure may be detected when detecting that the DESAT voltage Vd2 exceeds the DESAT voltage threshold Y1 at a time t52 after a filtering time elapses from a time t51 at which the gate voltage Vg2 exceeds the gate voltage threshold X1. In FIG. 10, the DESAT voltage Vd2 exceeds the DESAT voltage threshold Y1 at a time earlier than the time t52, but a short-circuit failure is firstly detected at a time t52.

The short-circuit detecting circuits 20 and 30 are each configured to include a timer that measures an elapsed time from a predetermined timing, whereby a filtering time can be set. The predetermined timing is set to be a time when the gate voltage Vg exceeds a predetermined gate voltage threshold. A determination circuit is configured to detect a short-circuit of a semiconductor switching element when an elapsed time measured by the timer exceeds a predetermined time and the DESAT voltage exceeds a predetermined DESAT voltage.

According to the above-described embodiments, a case is exemplified in which an insulated gate type semiconductor switching element is IGBT. However, it is not limited thereto. The short-circuit detecting circuit according to the above-described embodiments may preferably be utilized for detecting a short-circuit of various insulated gate type semiconductor such as IGBT and MOSFET.

According to the above-described embodiments, the following effects and advantages can be obtained.

The short-circuit detecting circuits 20, 30 and 40 detect a short-circuit of an insulated gate type semiconductor element (e.g. IGBT 11). The short-circuit detecting circuits 20, 30 and 40 are applied to DESAT detecting circuits 1 and 10 provided with a diode (e.g. diode 12) of which the cathode is connected to a high potential side terminal of the semiconductor switching element and a capacitor 14 where a first end is connected to an anode side of the diode and a second end is connected to a low potential side terminal of the semiconductor switching element.

The short-circuit detecting circuits 20 and 30 includes a gate voltage terminal 22, a DESAT voltage terminal 21 and a determination circuit. The gate voltage terminal serves as a terminal through which a gate voltage Vg of the semiconductor switching element is acquired. The DESAT voltage terminal 21 acquires a voltage of the capacitor 14 as a DESAT voltage Vd. The determination circuit detects a short-circuit of the semiconductor switching element based on (i) the gate voltage exceeding a gate voltage threshold (e.g. X1) and (ii) the DESAT voltage Vd exceeding a predetermined DESAT voltage threshold (e.g. Y1). Since the masking time can be secured by detecting that the gate voltage exceeds the gate voltage threshold, the charging time of the capacitor can be designed to be shorter. As a result, a short-circuit of a semiconductor switching element can be promptly detected, and the semiconductor switching element where a short-circuit occurs can be promptly protected.

Similar to the DESAT detecting circuit 10, the DESAT detecting circuit may be connected to the capacitor 14 and may include a resistor element (e.g. charge resistor 17) that changes a rate of change of the DESAT voltage to be higher when switching the semiconductor switching element. Thus, the charging time of the capacitor 14 can be further shortened.

Similar to the short-circuit detecting circuit 20, the short-circuit detecting circuit may be further provided with a charge timing control circuit (e.g. wiring 31) that controls a charge-start timing of the capacitor 14 based on the gate voltage Vg. In this case, the charge timing control circuit may preferably control the start timing when the gate voltage Vg exceeds the gate voltage threshold.

The short-circuit detecting circuit may be further provided with a timer that measure a time elapsed from a predetermined timing. In this case, the predetermined timing may preferably be a time when the gate voltage exceeds a predetermined gate voltage threshold. Moreover, the determination circuit may be configured to detect that a short-circuit occurs on a semiconductor switching element when an elapsed time measured by the timer exceeds a predetermined time and the DESAT voltage exceeds a DESAT voltage threshold.

The gate voltage threshold may be higher or lower than a mirror voltage of a semiconductor switching element.

The short-circuit detecting circuit 40 includes a DESAT voltage terminal 21 serves as a terminal through a voltage at the capacitor 14 as a DESAT voltage Vd is acquired, a timer 41 that measures an elapsed time from a predetermined timing and a determination circuit that detects that a short-circuit on the semiconductor switching element has occurred when the elapsed time measured by the timer 41 exceeds a predetermined time and the DESAT voltage Vd exceeds a predetermined DESAT voltage threshold (e.g. Y4). Since the timer 41 secures a masking time, a charging time of the capacitor can be shortened in a design process. As a result, a short-circuit of a semiconductor switching element can be promptly detected, and the semiconductor switching element where a short-circuit occurs can be promptly protected.

Hereinafter, distinctive configurations obtained from respective embodiments will be described.

### [Configuration 1]

A short-circuit detecting circuit (20, 30), applied for a DESAT detecting circuit (1, 10) provided with a diode (12) of which the cathode is connected to a high potential side terminal of an insulated gate type semiconductor element (11) and a capacitor (14) of which the first end is connected to an anode side of the diode and a second end is connected to a low potential side of the semiconductor switching element, detecting a short-circuit of the semiconductor element, the short-circuit detecting circuit comprising:
a gate voltage terminal (21) though which a gate voltage of the semiconductor is acquired;
a DESAT voltage terminal (22) through which a desaturation voltage corresponding to a capacitor voltage of the capacitor is acquired; and
a determination circuit (28, 29) that detects, based on (i) the gate voltage exceeding a predetermined gate voltage threshold and (ii) the DESAT voltage exceeding a predetermined DESAT voltage threshold, a short-circuit of the semiconductor switching element.

### [Configuration 2]

The short-circuit detecting circuit according to configuration 1, wherein
the DESAT detecting circuit includes a resistor element (17) connected to the capacitor, changing a rate of change of the DESAT voltage to be higher when switching the semiconductor switching element.

### [Configuration 3]

The short-circuit detecting circuit according to configuration 1 or 2 further comprising:
a charge timing control circuit (31) that controls a charge-start timing of the capacitor based on the gate voltage,
   wherein
the charge timing control circuit controls the charge-start timing when the gate voltage exceeds a predetermined gate voltage threshold.

### [Configuration 4]

The short-circuit detecting circuit according to any one of configurations 1 to 3 further comprising:
a timer that measures an elapsed time from a predetermined timing,
   wherein
the predetermined timing is a timing when the gate voltage exceeds a predetermined gate voltage threshold;
the determination circuit detects a short-circuit on the semiconductor switching element when the elapsed time measured by the timer exceeds a predetermined time and the DESAT voltage exceeds a predetermined DESAT voltage threshold.

### [Configuration 5]

The short-circuit detecting circuit according to any one of configurations 1 to 4, wherein
the gate voltage threshold is higher than a mirror voltage of the semiconductor switching element.

### [Configuration 6]

The short-circuit detecting circuit according to any one of configurations 1 to 4, wherein
the gate voltage threshold is lower than a mirror voltage of the semiconductor switching element.

### [Configuration 7]

A short-circuit detecting circuit (40), applied for a DESAT detecting circuit (1) provided with a diode (12) of which the cathode is connected to a high potential side terminal of an insulated gate type semiconductor element (11) and a capacitor (14) of which the first end is connected to an anode side of the diode and a second end is connected to a low potential side of the semiconductor switching element, detecting a short-circuit of the semiconductor element, the short-circuit detecting circuit comprising:
a DESAT voltage terminal (22) through which a desaturation voltage corresponding to a capacitor voltage of the capacitor is acquired;
a timer (41) that measures an elapsed time from a predetermined timing; and
a determination circuit (28, 41) that detects a short-circuit on the semiconductor switching element when the elapsed time measured by the timer exceeds a predetermined time and the DESAT voltage exceeds a predetermined DESAT voltage threshold.

The present disclosure has been described in accordance with the embodiments. However, the present disclosure is not limited to the embodiments and structure thereof. The present disclosure includes various modification examples and modifications within the equivalent configurations. Further, various combinations and modes and other combinations and modes including one element or more or less elements of those various combinations are within the range and technical scope of the present disclosure.

### Conclusion

The present disclosure provides a technique that promptly detects a short-circuit of a semiconductor switching element.

The present disclosure provides first and second short-circuit detecting circuits applied for a DESAT detecting circuit provided with a diode of which the cathode is connected to a high potential side terminal of an insulated gate type semiconductor element and a capacitor of which the first end is connected to an anode side of the diode and a second end is connected to a low potential side of the semiconductor switching element, detecting a short-circuit of the semiconductor element. The first short-circuit detecting circuit includes: a gate voltage terminal though which a gate voltage of the semiconductor is acquired; a DESAT voltage terminal through which a desaturation voltage corresponding to a capacitor voltage of the capacitor is acquired; and a determination circuit that detects, based on (i) the gate voltage exceeding a predetermined gate voltage threshold and (ii) the DESAT voltage exceeding a predetermined DESAT voltage threshold, a short-circuit of the semiconductor switching element.

The first short-circuit detecting circuit according to the present disclosure is provided with a gate voltage terminal though which a gate voltage of the semiconductor is acquired and a DESAT voltage terminal through which a desaturation voltage corresponding to a capacitor voltage of the capacitor is acquired. Since it is detected that the gate voltage exceeds a predetermined gate voltage threshold, thereby a masking time is secured, the masking time is not necessarily adjusted for detecting a short-circuit with a design of the capacitor. Hence the charging time of the capacitor can be designed to be shorter. In other words, occurrence of a short-circuit on the semiconductor switching element is detected based on the gate voltage exceeding the gate voltage threshold and the DESAT voltage exceeding the DESAT voltage threshold, whereby the charging time of the capacitor can be shortened. Hence, a short-circuit of the semiconductor switching element can be promptly detected. As a result, for example, the semiconductor switching element where a short-circuit occurs can be promptly protected.

The second short-circuit detecting circuit according to the present disclosure is provided with a DESAT voltage terminal through which a desaturation voltage corresponding to a capacitor voltage of the capacitor is acquired, a timer that measures an elapsed time from a predetermined timing, and a determination circuit that detects a short-circuit on the semiconductor switching element when the elapsed time measured by the timer exceeds a predetermined time and the DESAT voltage exceeds a predetermined DESAT voltage threshold.

According to the second short-circuit detecting circuit, the masking time is secured by the timer, the masking time is not necessarily adjusted for detecting a short-circuit with a design of the capacitor. Hence, the charging time of the capacitor can be designed to be shorter. That is, a short-circuit of a semiconductor switching element is detected when an elapsed time measured by the timer exceeds a predetermined time and the DESAT voltage exceeds a predetermined DESAT voltage, whereby the charging time of the capacitor can be shortened. Hence, a short-circuit of the semiconductor switching element can be promptly detected. As a result, for example, the semiconductor switching element where a short-circuit occurs can be promptly protected.

What is claimed is:

1. A short-circuit detecting circuit, applied for a DESAT detecting circuit provided with a diode of which the cathode is connected to a high potential side terminal of an insulated gate type semiconductor switching element and a capacitor of which the first end is connected to an anode side of the diode and a second end is connected to a low potential side of the semiconductor switching element, detecting a short-circuit of the semiconductor element, the short-circuit detecting circuit comprising:
a gate voltage terminal though which a gate voltage of the semiconductor is acquired;
a DESAT voltage terminal through which a desaturation voltage corresponding to a capacitor voltage of the capacitor is acquired; and
a determination circuit that detects, based on (i) the gate voltage exceeding a predetermined gate voltage threshold and (ii) the DESAT voltage exceeding a predetermined DESAT voltage threshold, a short-circuit of the semiconductor switching element,
wherein
when no short-circuit failure occurs on the semiconductor switching element, the gate voltage starts to increase when the semiconductor switching element turns ON and stops the increase to reach a mirror voltage, then the gate voltage restarts to increase to become a constant voltage; and
the gate voltage threshold is higher than the mirror voltage of the semiconductor switching element.

2. The short-circuit detecting circuit according to claim 1,
wherein
the DESAT detecting circuit includes a resistor element connected to the capacitor, changing a rate of change of the DESAT voltage to be higher when switching the semiconductor switching element.

3. The short-circuit detecting circuit according to claim 2 further comprising a charge timing control circuit,
wherein
the determination circuit includes a comparator of which a logical state of an output signal changes to be H when the gate voltage exceeds the gate voltage threshold; and
the charge timing control circuit is configured to connect between a gate of a MOSFET connected in parallel to the capacitor and an output terminal of the comparator, and supplies a logical inversion signal of an output signal of the comparator to the gate of the MOSFET.
